(19) United States
(12) Patent Application Publication
(10) Pub. No.: US 2010/0002738 A1
(43) Pub. Date: Jan. 7, 2010

(54) Nitride-based semiconductor light-emitting device

(75) Inventors: Teruyoshi Takakura, Osaka (JP); Yuhzoh Tsuda, Osaka (JP); Masataka Ohta, Osaka (JP)

Correspondence Address: HARNESS, DICKEY & PIERCE, P.L.C., P.O. BOX 8910, RESTON, VA, 20195, US

(73) Assignee: Sharp Kabushiki Kaisha

(21) Appl. No.: 12/458,128

(22) Filed: Jul. 1, 2009

(30) Foreign Application Priority Data
Jul. 2, 2008 (JP) 2008-173325

(51) Int. Cl. H01S 5/00

(52) U.S. Cl. 372/44.011

(57) ABSTRACT

It is intended to improve operation characteristics of a nitride-based semiconductor light-emitting device including a nitride-based semiconductor crystal substrate having a main surface of a non-polarity plane.

A nitride-based semiconductor light-emitting device includes a nitride-based semiconductor crystal substrate and semiconductor stacked-layer structure of crystalline nitride-based semiconductor formed on a main surface of the substrate, wherein the semiconductor staked-layer structure includes an active layer sandwiched between an n-type layer and a p-type layer, the main surface of the substrate has a crystallographic plane tilted from a {10-10} plane of the nitride-based semiconductor crystal by an angle of more than −0.5° and less than −0.05° or more than +0.05° and less than +0.5° about a <0001> axis.

This nonprovisional application is based on Japanese Patent Application No. 2008-173325 filed on Jul. 2, 2008 with the Japan Patent Office, the entire contents of which are hereby incorporated by reference.

### BACKGROUND OF THE INVENTION

1. Field of the Invention

The present invention is related to a nitride-based semiconductor light-emitting device and particularly to improvements in characteristics of a nitride-based semiconductor light-emitting device including a nitride-based semiconductor crystal substrate.

2. Description of the Background Art

In recent years, an optical disk system utilizing a nitride-based semiconductor laser device for the purpose of high-density recording is brought into practical use. Such an optical disk system needs a highly reliable semiconductor laser device capable of emitting blue light at high power in order to enable high-density recording (e.g., double-layered disk), high-speed recording at more than double the normal speed, and the like. A light-emitting device utilizing nitride semiconductor is also desirable for an illumination device, a display device such as a projector, or the like. A laser device capable of emitting bluish violet light of about 405 nm wavelength is suitable for an optical disk system. Laser devices and LEDs (light-emitting diodes) capable of emitting pure blue light of about 445 nm wavelength and pure green light of about 550 nm wavelength are suitable for display devices. Laser devices and LEDs capable of emitting light of about 405 nm wavelength and about 450 nm wavelength are suitable for illumination devices.

Under the circumstances, Jpn. J. Appl. Phys. Vol. 39 (2000) pp. L647-L650, for example, discloses a nitride-based semiconductor laser element formed on a nitride-based semiconductor crystal substrate, which is capable of emitting light of 405 nm wavelength. Further, Japanese Patent Laying-Open No. 2004-087565 discloses a nitride-based semiconductor laser element formed on a nitride-based semiconductor crystal substrate, which is capable of emitting light of 450 nm wavelength.

FIG. 1 is a front view showing an exemplary stacked-layer structure of a nitride-based semiconductor laser device including a nitride-based semiconductor crystal substrate. FIG. 2 is a side view of the laser device of FIG. 1. On an n-type GaN substrate 101 in this laser device, an n-type GaN layer 102; an n-type AlGaN clad layer 103 for causing the optical confinement effect; an n-type GaN optical guide layer 104 for distributing light in the vicinity of an active layer; an active layer 105 having a multi-quantum well (MQW) structure that includes InGaN quantum well layers and InGaN barrier layers having respective different In composition ratios (atomic ratios of In in III-group elements); a p-type AlGaN carrier block layer 106 for improving efficiency of confining carriers into the active layer; a p-type GaN optical guide layer 107 for distributing light in the vicinity of the active layer; a p-type AlGaN clad layer 108 for causing the optical confinement effect; and a p-type GaN contact layer 109 are stacked in this order by epitaxial growth.

The laser device shown in FIGS. 1 and 2 usually includes a stripe ridge 110 formed by dry etching such as RIE (reactive ion etching). This stripe ridge causes the effect confining light in the lateral direction of the cavity. Upper surfaces of p-type clad layer 108 and side surfaces of ridge 110, which are exposed by etching, are covered with insulator films 111. A positive electrode 112 is deposited by vacuum evaporation so as to cover p-type contact layer 109 at the top of ridge 110 and then a negative electrode 113 is deposited on the bottom surface of n-type GaN substrate by vacuum evaporation.

After formation of these positive electrode 112 and negative electrode 113, the stacked-layer body shown in FIG. 1 is cleaved to have a length of several hundred μm in a direction perpendicular to the drawing sheet and have both end faces of the cavity. As shown in FIG. 2, an AR (antireflection) coating film 114 of a dielectric multilayered film for adjusting reflectance is formed on the front face of the cavity by vacuum evaporation and an HR (high reflection) coating film 115 of a dielectric multilayered film is formed on the rear face of the cavity by vacuum evaporation. Laser light is emitted from the front face of the cavity which is covered with AR coating film 114.

After formation of the coating films on both the end faces of the cavity, the stacked-layer body is cut in a direction parallel to the axis of the cavity so as to obtain a laser chip as shown in FIGS. 1 and 2. Such a laser chip is usually mounted on a sub-mount having a high thermal conductivity for heat dissipation during operation and then sealed on a stem to complete a semiconductor laser device.

A semiconductor light-emitting device capable of emitting light in a relatively longer wavelength range from blue to green with high output, high efficiency and long lifetime is desirable as a light source for a display device, an illumination device, or the like. A semiconductor light-emitting device for such intended use should emit light of a longer wavelength as compared to a semiconductor light-emitting device for an optical disk system and thus the In composition ratio should be increased in its light-emitting layer (active layer). Furthermore, in order to increase the output power and improve the emission efficiency, it is necessary to reduce the defects acting as non-radiative centers in the light-emitting layer and reduce the operation voltage.

A schematic perspective view of FIG. 3 shows primary crystallographic axes and planes of a hexagonal nitride-based semiconductor crystal that is utilized for a light-emitting device. In this figure, the top and bottom surfaces of the hexagonal column are a crystallographic {0001} plane that is also called a C-plane in short. An axis perpendicular to this {0001} plane is a <0001> axis that is also called a C-axis in short. The side surfaces of the hexagonal column are a {10-10} plane that is also called an M-plane in short. An axis perpendicular to this {10-10} plane is a <10-10> axis that is also called an M-axis in short. An axis containing the center point and a vertex of the hexagonal C-plane is a <11-20> axis that is also called an A-axis in short. A plane perpendicular to this <11-20> axis is a {11-20} plane that is also called an A-plane in short. As seen in FIG. 3, the C-axis, M-axis and A-axis in a hexagonal nitride-based semiconductor crystal are perpendicular to each other.

FIG. 4 is a schematic perspective view of a conventional nitride-based semiconductor crystal substrate having a main surface of a C-plane. In the case that a nitride-based semiconductor light-emitting element having a light emitting layer containing In is formed on such a conventional GaN substrate having a main surface of a C-plane (also called a C-plane GaN substrate in short), it is known that a piezoelectric field is generated due to crystal lattice strain in the light-emitting layer. The reason for generation of this piezoelectric field is that atomic planes of III-group element and atomic planes of V-group element that are parallel to a C-plane are alternately stacked in a C-axis direction. For this reason, the C-plane of a nitride-based semiconductor crystal is called a polarity plane.

A nitride-based semiconductor light-emitting device using a C-plane GaN substrate having polarity is liable to lower in its output, emission efficiency, and reliability. Influence of crystalline quality and special separation of carriers due to the piezoelectric field in the light-emitting layer are considered as the cause of this lowering. Specifically, the piezoelectric field caused by stress due to lattice mismatch between nitride-based semiconductor layers having respective different composition ratios tilts the valence band and conduction band in the light-emitting layer. Therefore, electrons and positive holes as carriers injected in the light-emitting layer are specially separated and localized in the regions of potentials lowest for electrons and positive holes respectively, whereby causing decrease in efficiency of radiative recombination of carriers. Furthermore, the piezoelectric field is shielded as the density of injected carriers is increased in the light-emitting layer and then this cause a problem of a wavelength shift in light emission.

To avoid such problems originating from the polarity GaN substrate as described above, a nitride-based semiconductor laser device using a non-polarity GaN substrate has recently been studied and developed. As a non-polarity GaN substrate, it is possible to use a nitride-based semiconductor crystal substrate having a main surface of a non-polarity M-plane perpendicular to a polarity C-plane (also called an M-plane substrate in short).

FIG. 5 is a schematic perspective view of a nitride-based semiconductor crystal substrate having a main surface of an M-plane. The present inventors have found that in the case of crystal-growing a nitride-based semiconductor stacked-layer structure of a light-emitting device on the prior-art non-polarity M-plane substrate shown in FIG. 5, the top surface of the stacked-layer structure does not become flat and is liable to include relatively large unevenness. Specifically, in the case of crystal-growing the nitride-based semiconductor stacked-layer structure of a light-emitting device on the M-plane substrate, the top surface of the stacked-layer structure causes unevenness as large as arithmetic average roughness Ra of about 20 nm to 200 nm. Such unevenness on the top surface of the laser device may be a cause of light scattering in the cavity and then a cause of deterioration in threshold current and slope efficiency (ΔP/ΔI: ΔI denotes increment of current and ΔP denotes increment of optical output) in the laser device. In the case of forming a nitride-based semiconductor light-emitting device using a non-polarity nitride-based semiconductor crystal substrate, therefore, it is desired to improve the flatness of the top surface of the light-emitting device.

### SUMMARY OF THE INVENTION

In view of the prior art status as described above, an object of the present invention is to improve operation characteristics of a nitride-based semiconductor light-emitting device including a nitride-based semiconductor crystal substrate having a non-polarity main surface.

A nitride-based semiconductor light-emitting device according to the present invention includes a nitride-based semiconductor crystal substrate and semiconductor stacked-layer structure of crystalline nitride-based semiconductor formed on a main surface of the substrate, wherein the semiconductor staked-layer structure includes an active layer sandwiched between an n-type layer and a p-type layer, the main surface of the substrate has a crystallographic plane tilted from a {10-10} plane of the nitride-based semiconductor crystal by an angle of more than −0.5° and less than −0.05° or more than +0.05° and less than +0.5° about a <0001> axis.

The nitride-based semiconductor light-emitting device can be a laser device including a cavity, wherein the cavity may have its lengthwise direction parallel to a <0001> direction and both end faces of a {0001} plane.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic front view of a stacked-layer structure of an exemplary nitride-based semiconductor light-emitting device;

FIG. 2 is a side view of the light-emitting device of FIG. 1;

FIG. 3 is a schematic perspective view showing primary crystallographic axes and planes of a hexagonal nitride-based semiconductor crystal;

FIG. 4 is a schematic perspective view of a nitride-based semiconductor crystal substrate having a main surface of a C-plane;

FIG. 5 is a schematic perspective view of a nitride-based semiconductor crystal substrate having a main surface of an M-plane;

FIG. 6 is a schematic perspective view of a nitride-based semiconductor crystal substrate having a main surface of an Mθ-plane that is tilted from an M-plane by a small angle of θ about a C-axis;

FIG. 7 is a schematic cross-sectional view showing atomic steps on the tilted main surface of the Mθ-plane substrate of FIG. 6;

FIG. 8 is a graph showing influence of the tilt angle θ of the Mθ-plane substrate on the threshold current of the nitride-based semiconductor light-emitting device formed with that substrate; and

FIG. 9 is a graph showing influence of the tilt angle θ of the Mθ-plane substrate on the slope efficiency of the nitride-based semiconductor light-emitting device formed with that substrate.

### DESCRIPTION OF THE PREFERRED EMBODIMENTS

### Embodiment 1

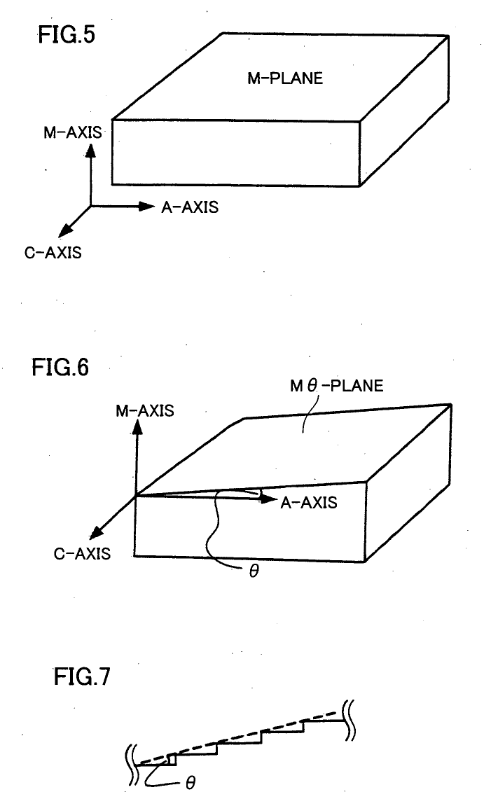

FIG. 6 is a schematic perspective view of a nitride-based semiconductor crystal substrate that can be used for formation of a nitride-based semiconductor light-emitting device according to Embodiment 1 of the present invention. The upper main surface of this substrate has a crystallographic plane tilted from a {10-10} plane (M-plane) by a small angle θ about a C-axis (referred to as an Mθ-plane in this specification). Hereinafter, such a substrate is also called an Mθ-plane nitride-based semiconductor crystal substrate.

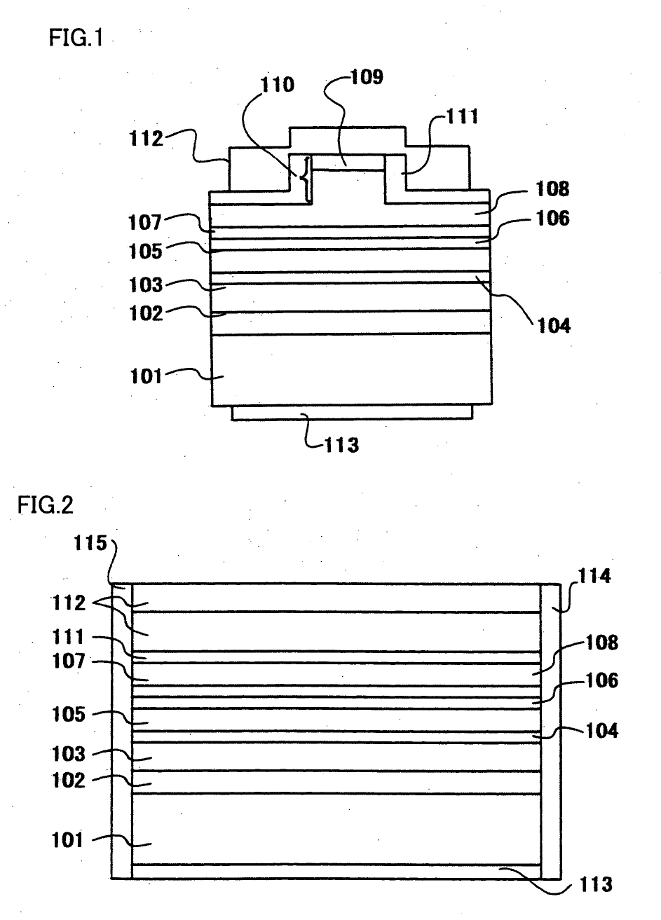

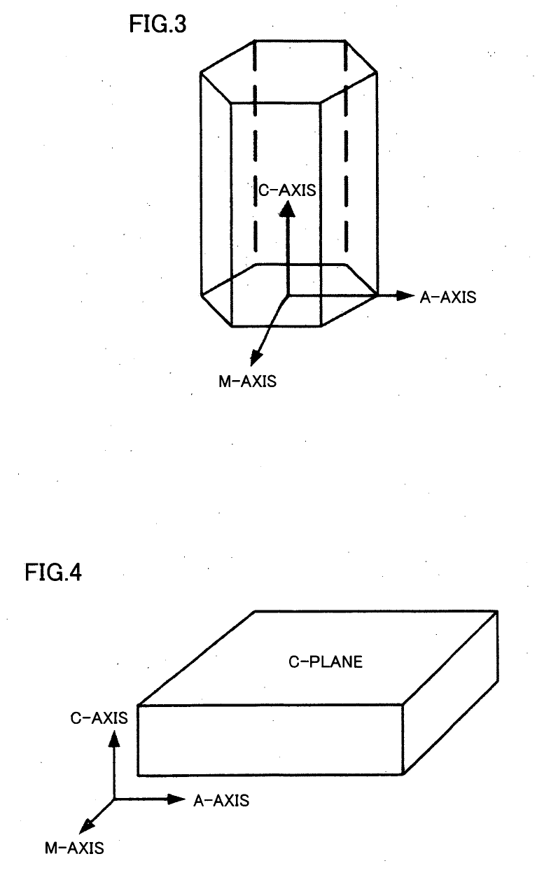

FIGS. 1 and 2 can be referred to also regarding a nitride-based semiconductor light-emitting device according to Embodiment 1 of the present invention. In formation of a nitride-based semiconductor light-emitting device according to Embodiment 1, on an n-type Mθ-plane GaN substrate 101; an n-type GaN layer 102 of 0.2 μm thickness; an n-type Al_{0.05}Ga_{0.95}N clad layer 103 of 2.5 μm thickness; an n-type GaN guide layer 104 of 0.1 μm thickness; an MQW active layer 105 including four InGaN barrier layers each having a thickness of 8 nm and three InGaN well layers each having a thickness of 4 nm that are alternately stacked; a p-type Al_{0.3}Ga_{0.7}N carrier block layer 106 of 20 nm thickness; a p-type GaN guide layer 107 of 0.08 μm thickness; a p-type Al_{0.062}Ga_{0.938}N clad layer 108 of 0.5 μm thickness; and a p-type GaN contact layer 109 of 0.1 μm thickness are stacked in this order by MOCVD (metal-organic chemical vapor deposition).

In Embodiment 1 as described above, the MQW active layer 105 includes a barrier layer/a well layer/a barrier layer/a well layer/a barrier layer/a well layer/a barrier layer formed in this order. However, the stacking layer number is not restricted to a particular number and it is also possible to use a stacking structure in which the stacking starts from a well layer and ends with also a well layer such as a well layer/a barrier layer/a well layer/barrier layer . . . /a well layer.

As a source material for growing a nitride-based semiconductor crystal, it is possible to use NH₃ (ammonia) for a source of nitrogen of a V-group element. It is also possible to use TMG (trimethylgallium), TMI (trimethylindium) and TMA (trimethylaluminum) for sources of Ga, In and Al of III-group elements, respectively. Regarding each nitride-based semiconductor layer, the crystal growth rate can be controlled by adjusting the supply amount of the III-group elements, and the composition ratio in the mixed crystal (ratios between III-group elements in the mixed crystal) can also been controlled by adjusting the supply ratios between two or more III-group elements.

In the case of growing a mixed crystal of Al_{0.05}Ga_{0.95}N, for example, the vapor phase ratio of 2TMA/(2TMA+TMG) may be set to 0.05 in principle. As a matter of fact, however, due to influence of reaction in the vapor phase and use efficiency of the source materials, the vapor phase ratio should be increased as compared to the principle vapor phase ratio for the intended Al composition ratio. In the case of growing a mixed crystal of Al_{0.1}Ga_{0.9}N, the vapor phase ratio of 2TMA/(2TMA+TMG) may be doubled as compared to the case of Al_{0.05}Ga_{0.95}N. In this case also, the vapor phase ratio should be increased because of influence of the vapor phase reaction and the like in the actual crystal growth as compared to the principle vapor phase ratio. Incidentally, the reason why the supply amount of TMA is doubled as compared to TMG in the formula of the vapor phase ratio is that TMA is a dimer. In the case of TMI, the principle vapor phase ratio is represented with TMI/(TMI+TMG). Further, while the vapor phase ratio and the mixed crystal composition ratio are in a proportional relation, the line representing the proportional relation in a graph usually has an intercept with the axis representing the mixed crystal composition ratio. This is usually because there are portions of source materials that are not taken into the mixed crystal composition ratio during the vapor phase reaction. In other words, the source materials can be taken into the mixed crystal composition ratio only by being supplied at respective amounts more than those to be consumed by the vapor phase reaction.

In general, Si is used as an n-type impurity for the nitride-based semiconductor, and the impurity concentration is usually in the order of 10¹⁸ cm⁻³. It is known that the n-type impurity is activated at 100% at a room temperature in the nitride-based semiconductor crystal as grown, and thus the n-type carrier concentration is approximately equal to the impurity concentration. It is also possible to use C, Ge and O other than Si as the n-type impurity. While Mg is generally used as a p-type impurity for the nitride-based semiconductor, it is also possible to use Zn and Be or mixture thereof. Mg is usually supplied as Cp₂Mg (biscyclopentadienyl magnesium) or EtCp₂Mg (ethyl biscyclopentadienyl magnesium) during crystal growth.

The p-type impurity in the nitride-based semiconductor crystal as grown is bonded with H and thus inactivated. In order to activate the p-type impurity, therefore, a heat treatment or an electron beam treatment is carried out after growth of the crystal. In general, the heat treatment is more preferable for the activation of the p-type impurity from the viewpoint of the productivity and carried out at about 800-900° C. for about 30 minutes at most. As an atmosphere for the heat treatment, it is possible to use a N₂ gas or a mixed gas of N₂ and O₂. In the case of using this mixed gas, the O₂ concentration is in the order of one digit % at most.

P-type Al_{0.062}Ga_{0.938}N clad layer 108 and p-type GaN contact layer 109 are partially etched by dry etching such as RIE or ICP (inductively-coupled plasma) to form a stripe ridge 110. The upper surfaces of p-type clad layer 108 and side surfaces of ridge 110, which are exposed by the etching, are covered with insulator (SiO₂, ZrO₂, or the like) films 111. Then, a positive electrode 112 is deposited by vacuum evaporation to cover p-type GaN contact layer 109 at the top of ridge 110.

Thereafter, Mθ-plane GaN substrate 101 is ground or polished on its bottom surface to have a thickness of about 100 μm. A damaged layer caused by the grinding or polishing on the bottom surface of Mθ-plane GaN substrate 101 is removed by vapor phase etching such as RIE. On the etched bottom surface of substrate 101, a negative electrode (Ti/Al) 113 is formed by EB (electron beam) evaporation. The wafer provided with negative electrode 113 is then cut into a plurality of bars so as to form both end faces of each cavity. On the end faces of the cavity obtained as such, an AR coating film 114 and an HR coating film 115 are formed respectively as seen in FIG. 2.

In the Mθ-plane substrate used in the present Embodiment, the tilt angle θ shown in FIG. 6 is set to 0.5°. In other words, the Mθ-plane substrate used in the present Embodiment has an upper main surface tilted by 0.5° about a C-axis from an M-plane. Such an Mθ-plane having a small tilt angle with respect to the non-polarity M-plane perpendicular to the polarity C-plane is also a non-polarity plane similar to the M-plane. In the present Embodiment, the nitride-based semiconductor light-emitting device is designed to have a lasing wavelength of 450 nm and emit pure blue light. For this end, it is necessary that the well layers have an In composition ratio of about 20%.

Characteristics of a nitride-based semiconductor light-emitting device obtained using an Mθ-plane substrate in the present Embodiment were compared with those of nitride-based semiconductor light-emitting devices formed respectively using the prior-art M-plane substrate and the conventional C-plane substrate. In this case, the nitride-based semiconductor light-emitting devices including respective different substrates were formed by respective separated MOCVD. The reason of this is that since the growth rate and mixed crystal composition ratio of each nitride-based semiconductor layer are influenced by the main surface orientation of the substrate, it is difficult to form the nitride-based semiconductor stacked-layer structures as designed in the same reaction chamber by concurrent MOCVD crystal growth.

Regarding the nitride-based semiconductor stacked-layer structures obtained using the Mθ-plane substrate, M-plane substrate and C-plane substrate, the average In composition ratio of the well layers included in each of the semiconductor stacked-layer structures was measured and it was found that the In composition ratio was 20% as designed in any case of using any of the substrates.

Further, when the unevenness on the top surface of each of the nitride-based semiconductor stacked-layer structures was measured with a profilometer, the arithmetic average roughness Ra was about 3 nm in the case of having used the Mθ-plane substrate, about 56 nm in the case of having used the M-plane substrate, and about 3 nm in the case of having used the C-plane substrate. It is understood from this that while the average roughness Ra becomes very large in the case of using the prior-art non-polarity M-plane substrate as compared to that in the case of using the conventional polarity C-plane substrate, the average roughness Ra in the case of using the non-polarity Mθ-plane substrate according to the present Embodiment is as small as that in the case of using the conventional polarity C-plane substrate. In other words, it is possible to suppress the unevenness on the top surface of the nitride-based semiconductor stacked-layer structure by using a plane tilted with a small angle from the M-plane as a main surface of the nitride-based semiconductor crystal substrate.

When the status of the top surface of the nitride-based semiconductor stacked-layer structure grown on the M-plane substrate was observed with an interference microscope, it was found that characteristic unevenness including stripe-like ridges were generated and the lengthwise direction of the, stripe-like ridges was approximately parallel to the C-axis. At the top surface of the nitride-based semiconductor stacked-layer structure grown on the Mθ-plane substrate, on the other hand, such stripe-like ridges as seen in the case of having used the M-plane substrate have almost disappeared, and this corresponds to the improvement in the Ra value. As a mechanism of suppression of the unevenness on the top surface of the nitride-based semiconductor stacked-layer structure in the case of using the Mθ-plane substrate, it is considered that atomic steps formed on the substrate surface tilted by a small angle from the M-plane cause orderly step-flow-growth in the lateral direction.

FIG. 7 is a schematic cross-sectional view showing atomic steps on the Mθ-plane of the FIG. 6 substrate. The top face (tread) of each step is formed with a {10-10} plane (M-plane) that has a high atomic density and is stable. On the other hand, the side face (riser) of each step is formed with an atomic small level-difference. In such a situation, atoms from their vapor phase adhere to portions having the small level-difference (riser) and thus the steps cause the step-flow-growth in the lateral direction. When a crystal layer grows with such step-flow-growth, it is predicted that there is a certain restricted range in the tilt angle of the main surface of the Mθ-plane substrate in order to grow a crystal layer of a good quality.

Each of the nitride-based semiconductor stacked-layer structures grown on the Mθ-plane substrate, the M-plane substrate and the C-plane substrate respectively as described above was subjected to a heat treatment at 900° C. for 10 minutes in an atmosphere of N₂ to activate Mg. In separate experiments, it was found that either of p-type GaN and p-type AlGaN subjected to a heat treatment at a temperature from 700° C. to 950° C. within 30 minutes showed p-type conductivity. In these cases, the atmosphere of the heat treatment was an atmosphere of N₂ containing O₂ of 5% at most.

Each of the nitride-based semiconductor stacked-layer structures obtained using the Mθ-plane substrate, the M-plane substrate and the C-plane substrate respectively as described above was then subjected to the ordinary processes and cut into chips. Each chip was mounted on a stem to complete a nitride-based semiconductor light-emitting device. Evaluations were conducted on the characteristics of the nitride-based semiconductor light-emitting devices thus obtained.

Incidentally, the lengthwise direction of the cavity in the light-emitting device including the C-plane substrate was set parallel to the M-axis direction. The reason of this is that a cleavage plane of the C-plane substrate is an M-plane perpendicular to an M-axis and thus end faces of the cavity can be formed by cleavage. In each of the light-emitting devices including the Mθ-plane substrate and the Mθ-plane substrate respectively, on the other hand, the lengthwise direction of the cavity was set parallel to the C-axis and the end faces of the cavity were formed with the C-plane. The reason of this is that the polarization plane of light is parallel to a C-axis and thus intensity of light emitted from a C-plane is higher as compare to that of light emitted from the other planes.

While the C-plane is not a cleavage plane, the end face of the cavity can be formed by ICP, RIE, or the like. It is also possible to form the cavity end face parallel to the C-plane by pseudo-cleavage. In this case, grooves parallel to the C-plane are formed from the substrate 101 side so as not to reach ridge 110, for example, and then the end faces of the cavity can be formed by pseudo-cleavage along the grooves.

As a result of measuring the lasing threshold current regarding the three kinds of the light-emitting devices formed as described above, the light-emitting devices including the Mθ-plane substrate, the M-plane substrate and the C-plane substrate showed the threshold currents of 20 mA, 40 mA and 60 mA, respectively.

Further, as a result of evaluating the slope efficiency regarding the three kinds of the light-emitting devices, the light-emitting devices including the Mθ-plane substrate, the M-plane substrate and the C-plane substrate showed the slope efficiency of 1.5 W/A, 0.85 W/A and 0.6 W/A, respectively.

As a reason why the threshold current and the slope efficiency of the light emitting device including the non-polarity M-plane substrate is improved as compared to the light-emitting device including the polarity C-plane substrate, it is considered that carriers injected into the active layer grown over the polarity C-plane substrate are specially separated under influence of the piezoelectric field. In other words, the special separation of carriers in the active layer lowers the efficiency of radiative recombination of carriers.

On the other hand, as a reason why the threshold current and the slope efficiency of the light emitting device including the non-polarity Mθ-plane substrate according to the present Embodiment is improved as compared to the light-emitting device including the non-polarity M-plane substrate, it is considered that the surface unevenness is suppressed on the upper surface of the nitride-based semiconductor sacked-layer structure grown on the Mθ-plane substrate. This means that the active layer becomes uniform and the surface unevenness in the stripe ridge, which is liable to scatter light, is reduced and thus the internal loss is decreased.

### Embodiment 2

Many nitride-based semiconductor light-emitting devices were formed in Embodiment 2 of the present invention. As compared to Embodiment 1, the light-emitting devices formed in Embodiment 2 were different only in that the tilt angle θ of the Mθ-plane substrate was variously changed in the range of 0° to 0.7°.

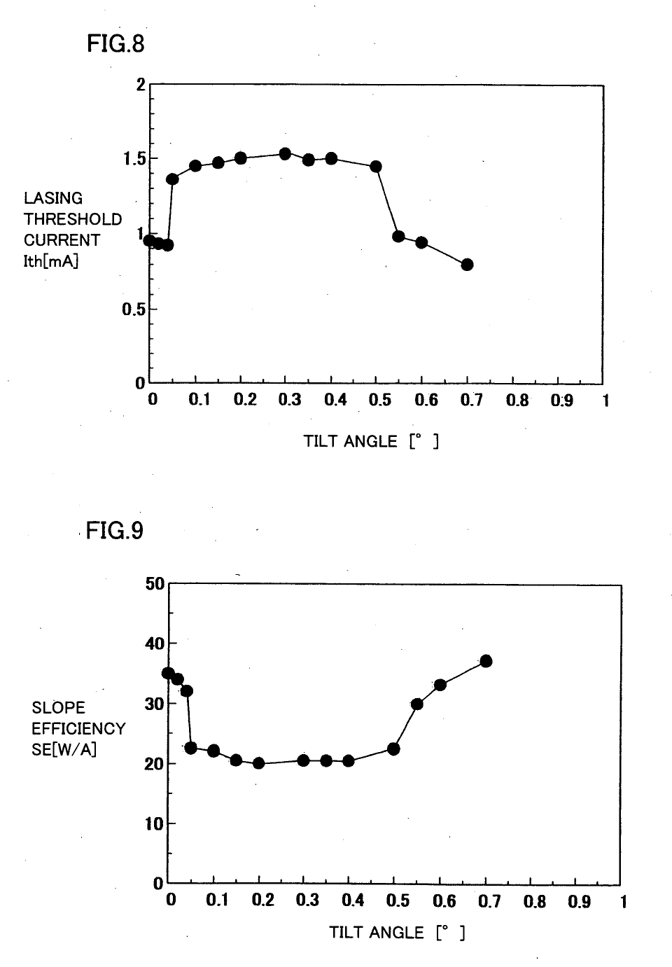

A graph of FIG. 8 shows the relation between the tilt angle [°] of the Me-plane substrate and the lasing threshold current Ith [mA] in the many light-emitting devices formed in Embodiment 2. It is seen from this graph that the result of the lower threshold current can be obtained in the range of the tilt angle θ from 0.05° to 0.5° for the Mθ-plane substrate.

Further, a graph of FIG. 9 shows the relation between the tilt angle [°] of the Mθ-plane substrate and the slope efficiency SE [W/A] in the many light-emitting devices formed in Embodiment 2. In this graph also, it is seen that the result of the higher slope efficiency can be obtained in the range of the tilt angle θ from 0.05° to 0.5° for the Mθ-plane substrate.

As a reason why both the threshold current and the slope efficiency are improved in the case of the tilt angle θ from 0.05° to 0.5° for the Mθ-plane substrate, the following matters may be considered. When the tilt angle θ shown in FIG. 7 is smaller than 0.05°, the interval (width of the top face of a step) between the atomic steps on the substrate surface is wide and thus vertical crystal-growth on the top face of the step becomes dominant as compared to lateral crystal-growth at the level-difference portion (riser) of the step, thereby, enlarging the surface unevenness. On the other hand, when the tilt angle θ is greater than 0.05°, the interval between the atomic steps on the substrate surface becomes very narrow and thus it becomes difficult to maintain the good lateral crystal-growth. Specifically, since the distance between the steps is short, lateral growth starting from the step riser is combined with lateral growth from the neighboring step riser and then causes irregular vertical growth covering the front of lateral growth. This irregular growth also enlarges the surface unevenness.

In other words, the atomic step density on the substrate surface becomes proper in the range of the tilt angle from 0.05° to 0.5°. Therefore, at the time when lateral growth originating from each atomic step riser reaches the neighboring step, the next lateral growth starts whereby maintaining the orderly step-flow-growth. Under the situation in which the step-flow-growth advances, the flatness of the top surface is maintained and it becomes possible that the Mθ-plane substrate also realizes the top surface flatness similarly to the case of the conventional C-plane substrate.

When the characteristic evaluation was conducted on the light-emitting device in the range of the tilt angle θ from −0.7° to 0° (i.e., the tilt angle θ is reversely rotated from a M-plane) in addition to the range of the tilt angle θ from 0° to 0.7°, the same result was obtained in the case of the negative tilt angle θ as in the case of the positive tilt angle θ. From this fact, it is considered that advance of the step-flow-growth does not depend on the positive or negative rotation of the tilt angle θ but depends only on the absolute value of the tilt angle θ, i.e., the atomic step density on the substrate surface.

### Embodiment 3

In Embodiment 3, a plurality of light-emitting devices including cavities in different directions regarding the crystallographic orientation were formed using the Mθ-plane substrate having the tilt angle of θ=0.3°. Specifically, the light-emitting device in Embodiment 3 is similar to that in Embodiment 1 except that the cavity is parallel to the C-axis and the end faces of the cavity are set to be the C-plane, or the cavity is parallel to the A-axis (perpendicular to the C-axis) and the end faces of the cavity are set to be the A-plane.

As a result of measuring the threshold current and the slope efficiency regarding the light-emitting devices in Embodiment 3, the threshold current was 20 mA and the slope efficiency was 1.5 W/A in the case of the light-emitting device including the cavity parallel to the C-axis. On the other hand, the light-emitting device including the cavity perpendicular to the C-axis showed a threshold current of 40 mA and a slope efficiency of 0.9 W/A, both the characteristics of which are inferior as compared to those of the light-emitting device including the cavity parallel to the C-axis.

As a reason why the characteristics of the light-emitting devices depend on the directions of the cavities, the following matters may be considered. In the case that the cavity is set parallel to the C-axis, since the lengthwise direction of the stripe-like ridges on the top surface of the semiconductor stacked-layer structure is approximately parallel to the C-axis as previously described, the effect of the flattening by using the tilted substrate is enhanced on the cavity and then it become possible to reduce the scattering loss of light propagating in the lengthwise direction of the cavity. In the light-emitting device including the cavity perpendicular to the C-axis, on the other hand, the lengthwise direction of the slightly remained stripe-like ridges is approximately perpendicular to the lengthwise direction of the cavity, and thus it is considered that the stripe-like ridges may act to scatter light propagating in the cavity.

As described above, the present invention can suppress generation of the unevenness on the top surface of a nitride-based semiconductor light-emitting device and can provide a nitride-based semiconductor light-emitting device improved in its operation characteristics.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride-based semiconductor light-emitting device comprising:
a nitride-based semiconductor crystal substrate and semiconductor stacked-layer structure of crystalline nitride-based semiconductor formed on a main surface of the substrate,
wherein the semiconductor staked-layer structure includes an active layer sandwiched between an n-type layer and a p-type layer, the main surface of the substrate has a crystallographic plane tilted from a {10-10} plane of the nitride-based semiconductor crystal by an angle of more than −0.5° and less than −0.05° or more than +0.05° and less than +0.5 about a <0001> axis.

2. The nitride-based semiconductor light-emitting device according to claim 1,
wherein said light-emitting device is a laser device including a cavity, and the cavity has its lengthwise direction parallel to a <0001> direction and both end faces of a {0001} plane.
